(19) United States
(12) Patent Application Publication
(10) Pub. No.: US 2007/0159012 A1
(43) Pub. Date: Jul. 12, 2007

(54) Acoustic equipment

(75) Inventors: Toshio Chamura, Tokyo (JP); Takashi Namioka, Tokyo (JP)

Correspondence Address: OLIFF & BERRIDGE, PLC, P.O. BOX 19928, ALEXANDRIA, VA, 22320, US

(73) Assignee: tDK Corporation, Tokyo (JP)

(21) Appl. No.: 10/582,685

(22) PCT Filed: Dec. 3, 2004
(86) PCT No.: PCT/JP04/18053

§ 371 Date: Jun. 13, 2006

(30) Foreign Application Priority Data
Dec. 18, 2003 (JP) 2003-420398

(51) Int. Cl. H01L 41/00

(52) U.S. Cl. 310/26

(57) ABSTRACT

An acoustic equipment has a columnar magnetostrictor 51, a drive coil 54, and a vibration transmitter 55. The columnar magnetostrictor 51 has one end where a partition 22 (stopper) is disposed to define the one end as a fixed end, and has the other end defined as a free end to allow the magnetostrictor 51 to expand and contract along an axial direction; the drive coil 54 is arranged to generate a magnetic field to expand and contract the columnar magnetostrictor 51 by a drive current based on an acoustic signal; the vibration transmitter 55 is disposed on the other end side of the columnar magnetostrictor 51 and is arranged to transmit vibration caused by expansion and contraction of the columnar magnetostrictor 51, to a plate 7; sponges 53a, 53b as elastic members are disposed between the partition 22 and the vibration transmitter 55 in the direction of the vibration.

### TECHNICAL FIELD

The present invention relates to acoustic equipment using a magnetostrictor.

### BACKGROUND ART

An example of the known acoustic equipment of this type is the one disclosed in Patent Document 1 below. This acoustic equipment has a columnar magnetostrictor, and a drive coil wound on a bobbin around the columnar magnetostrictor. In this case, the columnar magnetostrictor is so arranged that one end is in contact with a disc magnetic body and that the other end is in contact with an end of a magnetic member. In this case, the magnetic member is provided with a flange, and an elastic member is interposed between this flange and a case. Therefore, the magnetic member is biased toward the columnar magnetostrictor by the interposed elastic member, so as to be maintained in a state in which it can freely travel back and forth in the directions along the vibrating directions of the columnar magnetostrictor. In consequence, the disc magnetic body, the columnar magnetostrictor, and the magnetic member are integrally coupled so as to permit vibration of the columnar magnetostrictor.

In this acoustic equipment, when a drive current based on an acoustic signal is supplied, the drive coil generates a magnetic field oriented along the axial direction of the columnar magnetostrictor. On this occasion, the columnar magnetostrictor expands and contracts in the axial direction of the columnar magnetostrictor as the generated magnetic field is applied thereto. For this reason, the magnetic member vibrates in the axial direction of the columnar magnetostrictor in accordance with the expansion and contraction of the columnar magnetostrictor. Therefore, when this magnetic member is urged against a vibrator such as a diaphram, the vibration of the magnetic member is transmitted to the vibrator, whereupon the vibrator outputs sound.

Patent Document 1: Japanese Patent Application Laid-Open Gazette No. 9-261797 (page 3, FIG. 1)

### DISCLOSURE OF THE INVENTION

### Problem to be Solved by the Invention

However, this acoustic equipment has the following problem. Namely, this acoustic equipment has the disc magnetic body, the columnar magnetostrictor, and the magnetic member integrally coupled by the configuration wherein the magnetic member is biased toward the columnar magnetostrictor by the elastic member so as to permit the vibration of the columnar magnetostrictor. However, during periods in which the magnetic member is not urged against the vibrator, i.e., during stop periods of output of sound, the elastic member may fail to absorb displacement with expansion and contraction of the columnar magnetostrictor, for example, because of the vibration frequency of the columnar magnetostrictor, the magnitude of the vibration, and so on. In this case, the disc magnetic body, the columnar magnetostrictor, and the magnetic member become released from the integrally coupled state. Therefore, the disc magnetic body and the magnetic member, and the columnar magnetostrictor come into contact with each other with expansion and contraction of the columnar magnetostrictor, and it could result in inducing sound leakage based on the acoustic signal; it is thus preferable to make an improvement in this point.

The present invention has been accomplished in view of the problem to be solved, and a principal object of the invention is to provide an acoustic equipment capable of reducing the sound leakage during stop periods of output of sound.

### Means for Solving the Problem

In order to achieve the above object, an acoustic equipment according to the present invention comprises a columnar magnetostrictor which has one end where a stopper is disposed to define the one end as a fixed end and which has an other end defined as a free end to allow the columnar magnetostrictor to expand and contract along an axial direction; a magnetic field generator for generating a magnetic field to expand and contract the columnar magnetostrictor by a drive current based on an acoustic signal; and a vibration transmitter disposed on the other end side of the columnar magnetostrictor and arranged to transmit vibration caused by expansion and contraction of the columnar magnetostrictor, to a vibrator, wherein an elastic member is disposed between the stopper and the vibration transmitter in a direction of the vibration.

In this case, preferably, the elastic member is disposed in a state in which the elastic member can come into contact with at least one end face of the columnar magnetostrictor.

Preferably, the acoustic equipment comprises a magnet for generating a bias magnetic field, wherein the magnet is disposed in a state in which one end face of the magnet can come into contact with one end face of the columnar magnetostrictor, and wherein the elastic member is disposed in a state in which the elastic member can come into contact with another end face of the magnet.

### EFFECT OF THE INVENTION

In the acoustic equipment according to the present invention, the stopper is disposed on the one end side of the columnar magnetostrictor, the vibration transmitter is disposed on the other end side of the columnar magnetostrictor, and the elastic member is disposed between the stopper and the vibration transmitter; therefore, the elastic member absorbs displacement with expansion and contraction of the columnar magnetostrictor in a state in which the vibration transmitter is not urged against the vibrator. Accordingly, it is feasible to reduce the sound leakage due to contact between the columnar magnetostrictor and the members in the acoustic equipment including the stopper and the vibration transmitter. On the other hand, when the acoustic equipment is used to generate sound, the vibration transmitter is urged against the vibrator so as to contract the elastic member over its limit under which the elastic member can maintain elasticity. On this occasion, the elastic member functions as an inelastic body; therefore, the vibration due to the expansion and contraction of the columnar magnetostrictor is transmitted to the vibration transmitter and the vibration is transmitted through this vibration transmitter to the vibrator. As a result, the vibrator vibrates to output sound.

In the acoustic equipment according to the present invention, the elastic member is disposed in the state in which it can come into contact with at least one end face of the columnar magnetostrictor, whereby the elastic member directly absorbs the displacement with expansion and contraction of the columnar magnetostrictor in the state in which the vibration transmitter is not urged against the vibrator. Therefore, it is feasible to adequately reduce the sound leakage due to the contact between the columnar magnetostrictor and the other members.

In the acoustic equipment according to the present invention, the magnet is disposed in the state in which one end face of the magnet can come into contact with one end face of the columnar magnetostrictor, and the elastic member is disposed in the state in which it can come into contact with the other end face of the magnet; therefore, the elastic member directly absorbs the vibration of the magnet due to the expansion and contraction of the columnar magnetostrictor in the state in which the vibration transmitter is not urged against the vibrator. Accordingly, it is feasible to adequately reduce the sound leakage due to the contact between the magnet and the other members.

### BRIEF DESCRIPTION OF THE DRAWINGS

FIG. 1 is a sectional view showing a configuration of pencil type speaker 1.

FIG. 2 is a block diagram showing an electric circuit of pencil type speaker 1.

### DESCRIPTION OF REFERENCE SYMBOLS

1: pencil type speaker; 22: partition; 51: columnar magnetostrictor; 54: drive coil; 55: vibration transmitter; 52a, 52b: bias magnets; 53a, 53b: sponges.

### BEST MODES FOR CARRYING OUT THE INVENTION

The best mode of the acoustic equipment according to the present invention will be described below with reference to the accompanying drawings.

First, a configuration of pencil type speaker 1 to which the acoustic equipment according to the present invention is applied, will be described with reference to the drawings.

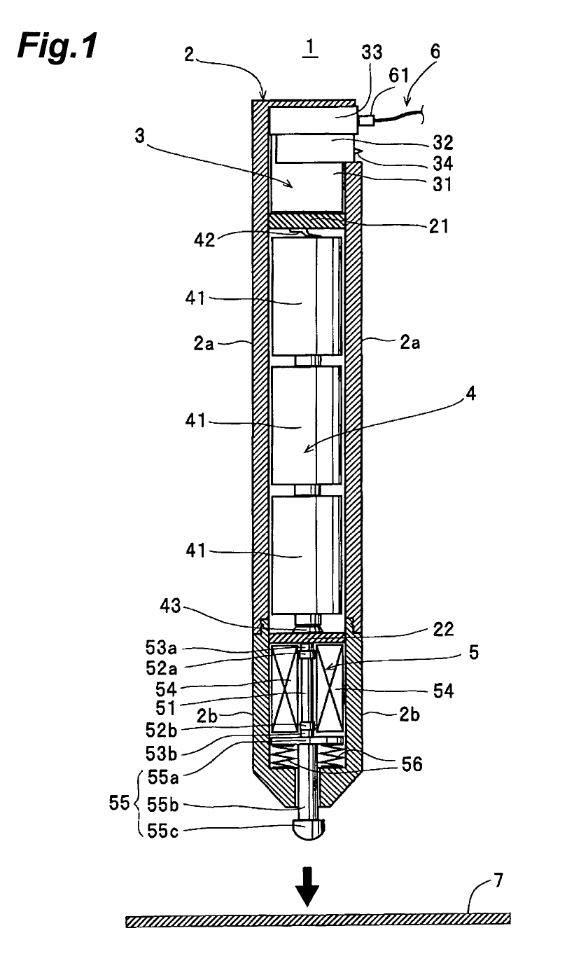

The pencil type speaker 1, as shown in FIG. 1, has a cylindrical housing 2, an acoustic signal amplifier 3, a power supply 4, and a vibration transducer 5, and is arranged to be able to output an acoustic signal when the tip of the pencil type speaker 1 is urged, for example, against a plate 7 as a vibrator. The housing 2, as shown in the same figure, is constructed with an upper housing body 2a and a lower housing body 2b each made of synthetic resin, and the two housing bodies 2a, 2b are integrally coupled through engagement between engaging parts formed at end portions thereof, thereby forming an elongated pencil shape as a whole. The upper housing body 2a is provided with a partition 21, the acoustic signal amplifier 3 is housed in an interior space on the rear end side partitioned by this partition 21, and the power supply 4 is housed in an interior space on the tip end side partitioned by the partition 21. On the other hand, another partition (stopper in the present invention) 22 for separating the power supply 4 from the vibration transducer 5 is fixed to the lower housing body 2b.

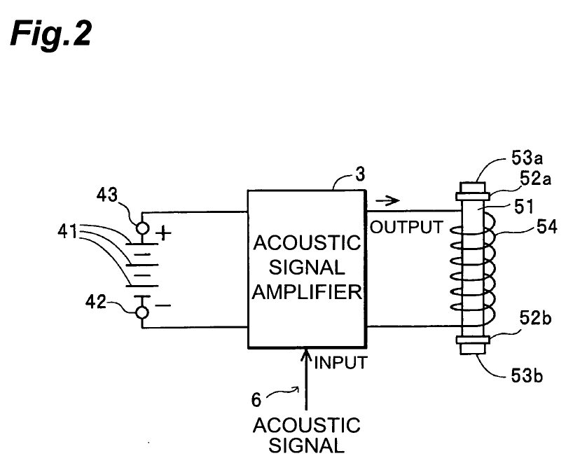

The acoustic signal amplifier 3, as shown in FIG. 2, amplifies an acoustic signal fed through an acoustic signal cable 6 from the outside and outputs a drive current generated, through an unrepresented connection cable to a drive coil 54. The acoustic signal amplifier 3, as shown in FIG. 1, is provided with an amplifier substrate 31 disposed on the rear end side of the upper housing body 2a, and a power switch 32 and an acoustic signal input connector 33 are mounted, as shown in the same figure, on this amplifier substrate 31. In this case, the power switch 32, as shown in the same figure, is provided with a knob 34 permitting a user to turn on and off the pencil type speaker 1 through switching operation. The acoustic signal input connector 33, as shown in the same figure, is constructed as a jack into which a plug 61 of the acoustic signal cable 6 for input of the acoustic signal from the outside can be inserted.

The power supply 4, as shown in FIGS. 1 and 2, is constructed as an example with three dry batteries 41, 41, 41, a battery terminal 42 fixed to the partition 21, and a battery terminal 43 fixed to the partition 22, and supplies power to the acoustic signal amplifier 3 through connection cables connected to the battery terminals 42, 43. In this case, the dry batteries 41 are taken in and out through an opening at the distal end of the upper housing body 2a in a state in which the upper housing body 2a is separated from the lower housing body 2b as the engaging parts are disengaged from each other.

The vibration transducer 5 is disposed in the interior space of the lower housing body 2b and, as shown in FIGS. 1 and 2, is constructed with a columnar magnetostrictor 51, bias magnets 52a, 52b, sponges 53a, 53b, a drive coil 54, a vibration transmitter 55, and, for example, four springs 56. The columnar magnetostrictor 51 functions as an element that expands and contracts in the axial direction with application of a magnetic field in a direction along the axial direction, to convert a variation of the magnetic field into mechanical vibration. The columnar magnetostrictor 51 is made, for example, of a giant magnetostrictive material having the central composition of Tb0.34-Dy0.66-Fe1.90, which produces a large displacement of approximately not less than 1500 ppm nor more than 2000 ppm in the axial direction in a magnetic field. One end of the columnar magnetostrictor 51 on the partition 22 side corresponds to the fixed end in the present invention, and the other end on the vibration transmitter 55 side corresponds to the free end in the present invention. The bias magnet 52a is fixed (or disposed) in a state in which one end face of the bias magnet 52a is in contact with an end face of the columnar magnetostrictor 51 on the upper housing body 2a side (corresponding to one end face of the columnar magnetostrictor in the present invention) and in which the other end face of the bias magnet 52a can come into contact through the sponge 53a with the partition 22. The bias magnet 52b is fixed (or disposed) in a state in which one end face of the bias magnet 52b is in contact with an end face of the columnar magnetostrictor 51 on the vibration transmitter 55 side (corresponding to one end face of the columnar magnetostrictor in the present invention) and in which the other end face of the bias magnet 52b can come into contact through the sponge 53b with a flange 55a (cf. FIG. 1) of the vibration transmitter 55. In this case, the bias magnets 52a, 52b correspond to the magnet in the present invention, and apply such a bias magnetic field as to be able to move the columnar magnetostrictor 51 between operating points to effect approximately linear expansion and contraction (vibration) against variation of the magnetic field in the axial direction.

The sponges 53a, 53b correspond to the elastic member in the present invention, function as elastic bodies before application of a predetermined pressure, and function as inelastic plates with application of an external force over the predetermined pressure while seldom functioning as elastic bodies. In this case, as described above, the sponge 53a is disposed between the partition 22 and the columnar magnetostrictor 51 in a state in which it can come into contact with the other end face of the bias magnet 52a, and the sponge 53b is disposed between the flange 55a and the columnar magnetostrictor 51 in a state in which it can come into contact with the other end face of the bias magnet 52b. The drive coil 54 corresponds to the magnetic field generator in the present invention and is disposed so that the center axis of the drive coil 54 is coaxial with the center axis of the columnar magnetostrictor 51, as shown in FIGS. 1 and 2. The drive coil 54, as shown in FIG. 2, generates the magnetic field on the axis of the drive coil 54 (or on the axis of the columnar magnetostrictor 51) with input of the drive current from the acoustic signal amplifier 3 through the connection cable.

The vibration transmitter 55, as shown in FIG. 1, is integrally constructed with the flange 55a of disc shape, shaft 55b, and tip contact part 55c. The flange 55a, as shown in the same figure, is in contact at the upper end face of the flange 55a with the sponge 53b and in contact at the lower end face of the flange 55a with the springs 56. Each spring 56, as shown in the same figure, is disposed in the interior space of the lower housing body 2b in a state in which one end thereof is in contact with the flange 55a while the other end is in contact with the inner wall of the lower housing body 2b and in which it biases the flange 55a toward the columnar magnetostrictor 51. The shaft 55b is so arranged that the tip contact part 55c is fixed to the distal end face of the shaft 55b, and transmits vibration of flange 55a to the tip contact part 55c. The tip contact part 55c, as shown in the same figure, has the tip end formed in a semispherical shape, as an example, and transmits vibration of the vibration transmitter 55 to the plate body 7 when urged against the plate body 7. As shown in the same figure, therefore, the springs 56 bias the flange 55a so as to integrally couple the flange 55a, sponge 53b, bias magnet 52b, columnar magnetostrictor 51, bias magnet 52a, and sponge 53a and so as to maintain the vibration transmitter 55 in a state in which it can travel back and forth (or can vibrate) along the axial direction of the vibration transmitter 55. In consequence, the vibration transmitter 55 moves away from the partition 22 with expansion of the columnar magnetostrictor 51, and moves toward the partition 22 with contraction of the columnar magnetostrictor 51. As a result, the vibration transmitter 55 (flange 55a) vibrates in the directions along the directions of expansion and contraction of the columnar magnetostrictor 51 in accordance with the expansion and contraction of the columnar magnetostrictor 51.

Next, the overall operation of the pencil type speaker 1 will be described.

While in this pencil type speaker 1 the tip contact part 55c of the vibration transmitter 55 is not urged against the plate body 7, i.e., during stop periods of output of sound, the acoustic signal amplifier 3 amplifies an acoustic signal fed through the acoustic signal cable 6 from the outside and supplies the drive current to the drive coil 54. On this occasion, the drive coil 54 applies the magnetic field generated based on the supplied drive current, to the columnar magnetostrictor 51. For this reason, the columnar magnetostrictor 51 expands and contracts in the axial direction according to the applied magnetic field. In this case, the springs 56 may fail to absorb the displacement with expansion and contraction of the columnar magnetostrictor 51, for example, because of the drive frequency of the columnar magnetostrictor 51, the magnitude of vibration, or the like, and during such occasions, the vibration transmitter 55, bias magnet 52b, columnar magnetostrictor 51, bias magnet 52a, and partition 22 become released from the integrally coupled state. In the pencil type speaker 1, however, the sponges 53a, 53b disposed between the flange 55a and the bias magnet 52b and between the bias magnet 52a and the partition 22 absorb the displacement due to the expansion and contraction of the columnar magnetostrictor 51 by elasticity of the sponges 53a, 53b during those occasions, so as to maintain the integral coupling of the vibration transmitter 55, bias magnet 52b, columnar magnetostrictor 51, bias magnet 52a, and partition 22. Therefore, the sound leakage due to contact between the members is reduced effectively and adequately.

On the other hand, when the tip contact part 55c is urged against the plate body 7 under such predetermined pressure as to contract the sponges 53a, 53b over the limit for retention of elasticity thereof, the partition 22 functions as a stopper (i.e., inertia mass together with the weights of a human hand and pencil type speaker 1), whereby the sponges 53a, 53b become compressed to function as inelastic plate bodies. Therefore, the vibration with expansion and contraction of the columnar magnetostrictor 51 is transmitted through the bias magnet 52b, the sponge 53b, the flange 55a, the shaft 55b, and the tip contact part 55c to the plate body 7 during this period. In this state, with vibration of the plate body 7, the acoustic signal fed from the outside is outputted as adequately audible sound from the plate body 7.

In this pencil type speaker 1, as described above, the partition 22 is disposed at one end of the columnar magnetostrictor 51, the vibration transmitter 55 is disposed at the other end of the columnar magnetostrictor 51, the sponge 53a is disposed between the partition 22 and the columnar magnetostrictor 51, and the sponge 53b is disposed between the flange 55a and the columnar magnetostrictor 51; therefore, the sponges 53a, 53b absorb the displacement due to the expansion and contraction of the columnar magnetostrictor 51 in the state in which the vibration transmitter 55 is not urged against the plate body 7. Accordingly, it is feasible to adequately reduce the sound leakage due to the contact of the columnar magnetostrictor 51 with the members such as the partition 22 and the bias magnets 52a, 52b in the pencil type speaker 1.

In the case of this columnar magnetostrictor 51, the sponges 53a, 53b are disposed in the state in which they can come into contact with the end faces of the bias magnets 52a, 52b, whereby the sponges 53a, 53b directly absorb the vibration of bias magnets 52a, 52b due to the expansion and contraction of the columnar magnetostrictor 51 in the state in which the vibration transmitter 55 is not urged against the plate body 7. Therefore, it is feasible to adequately reduce the sound leakage due to the contact between the bias magnets 52a, 52b and the other members.

The present invention is by no means limited to the above-described configuration. For example, the above configuration described the one provided with two sponges 53a, 53b, but it is also possible to adopt a configuration with only one of the sponges 53a, 53b, with sufficient effect of reducing the sound leakage.

The above described the configuration provided with the bias magnets 52a, 52b, but it is also possible to adopt a configuration without the bias magnets 52a, 52b, in which at least one of the sponges 53a, 53b is disposed so as to be able to contact at least one end face of the columnar magnetostrictor 51. In this configuration, at least one of the sponges 53a, 53b directly absorbs the displacement with expansion and contraction of the columnar magnetostrictor 51 in the state in which the vibration transmitter 55 is not urged against the plate body 7. Accordingly, it is feasible to adequately reduce the sound leakage due to the contact between the columnar magnetostrictor 51 and the other members.

The above described the configuration with the bias magnets 52a, 52b disposed at the both ends of the columnar magnetostrictor 51 (in the directly coupled state), but it is also possible to adopt a configuration wherein the bias magnets 52a, 52b and the columnar magnetostrictor 51 are not directly coupled and wherein a sponge is disposed at least between the columnar magnetostrictor 51 and one of the bias magnets 52a, 52b. This configuration can also adequately reduce the sound leakage in the same manner as the above configuration wherein at least one of the sponges 53a, 53b is disposed so as to be able to contact at least one end face of the columnar magnetostrictor 51.

The above described the configuration employing the sponges as the elastic member according to the present invention, but it is also possible to adopt a configuration using rubber, springs, disc springs, or the like, instead of the sponges. This configuration can also adequately reduce the sound leakage.

The above described the pencil type speaker 1 in the configuration with one columnar magnetostrictor 51, but the number of columnar magnetostrictor 51 is not limited to 1, and may be two or more. It is a matter of course that in this configuration a bias magnet and sponge may be optionally disposed between columnar magnetostrictors 51.

1. An acoustic equipment comprising:
a columnar magnetostrictor which has one end where a stopper is disposed to define the one end as a fixed end and which has an other end defined as a free end to allow the columnar magnetostrictor to expand and contract along an axial direction;
a magnetic field generator for generating a magnetic field to expand and contract the columnar magnetostrictor by a drive current based on an acoustic signal; and
a vibration transmitter disposed on the other end side of the columnar magnetostrictor and arranged to transmit vibration caused by expansion and contraction of the columnar magnetostrictor, to a vibrator,
wherein an elastic member is disposed between the stopper and the vibration transmitter in a direction of the vibration.

2. The acoustic equipment according to claim 1, wherein the elastic member is disposed in a state in which the elastic member can come into contact with at least one end face of the columnar magnetostrictor.

3. The acoustic equipment according to claim 1, comprising a magnet for generating a bias magnetic field,
wherein the magnet is disposed in a state in which one end face of the magnet can come into contact with one end face of the columnar magnetostrictor, and
wherein the elastic member is disposed in a state in which the elastic member can come into contact with another end face of the magnet.
